(19) United States
(12) Patent Application Publication
(10) Pub. No.: US 2018/0047678 A1
(43) Pub. Date: Feb. 15, 2018

(54) TFT LIQUID CRYSTAL MODULES, PACKAGE STRUCTURES, AND PACKAGE METHODS

(71) Applicant: Shenzhen China Star Optoelectronics Technology Co. Ltd., Shenzhen, Guangdong (CN)

(72) Inventor: Wenhui LI, Shenzhen, Guangdong (CN)

(73) Assignee: Shenzhen China Star Optoelectronics Technology Co. Ltd., Shenzhen, Guangdong (CN)

(21) Appl. No.: 14/915,265

(22) PCT Filed: Jan. 28, 2016
(86) PCT No.: PCT/CN2016/072552

§ 371 Date: Feb. 29, 2016

(30) Foreign Application Priority Data
Jan. 5, 2016 (CN) 201610005331.3

(51) Int. Cl. H01L 23/00; H01L 29/66; H01L 29/786; H01L 21/34

(52) U.S. Cl. CPC H01L 23/564; H01L 21/34; H01L 29/66969; H01L 29/7869

(57) ABSTRACT

The present disclosure relates to a TFT liquid crystal module, and the package structure and the package method thereof. The TFT package structure includes a first protection layer covering a surface of the TFT, a second protection layer arranged above the first protection layer, and a hydrophobic layer arranged above the second protection layer. With such configuration, the organic photoresist layer is formed on the external surface of the protection layer, and the plasma gas treatment is applied to the organic photoresist material to obtain the hydrophobic layer. As the hydrophobic layer does not absorb the moisture, that is, the moisture is cut off. Thus, the TFT performance may be kept stable.

### BACKGROUND OF THE INVENTION

### 1. Field of the Invention

The present disclosure relates to liquid crystal display (LCD) package structure technology, and more particularly to a TFT liquid crystal module, and the package structure and the package method thereof.

### 2. Discussion of the Related Art

Oxide semiconductor, such as Indium gallium zinc oxide (IGZO), includes certain issues regarding TFTs. FIG. 1 is a schematic view of the conventional TFT package structure.

Oxide semiconductor TFT may absorb moisture in the environment, which may change the TFT performance. Usually, a protection layer 3 is adopted to cut off the moisture. The protection layer 3 may be inorganic materials or organic materials. However, the moisture may be kept on the surface of the protection layer 3 or may pass through the protection layer 3 so as to penetrate the TFT unit 2, which may affect the performance of the TFT, wherein the reference numeral 1 relates to a glass substrate.

### SUMMARY

The present disclosure relates to a TFT liquid crystal module, and the package structure and the package method thereof to prevent the TFT package structure form being immersed by the moisture in the environment so as to enhance the TFT performance.

In one aspect, a TFT package structure includes: a first protection layer covering a surface of the TFT, a second protection layer arranged above the first protection layer, and a hydrophobic layer arranged above the second protection layer.

Wherein the hydrophobic layer is of one-layer structure or of multiple-layer structure.

Wherein the hydrophobic layer is made by organic photoresist material.

Wherein the hydrophobic layer is formed by applying a plasma treatment toward the organic photoresist material.

Wherein the first protection layer and the second protection layer are made by insulating materials.

Wherein the first protection layer and the second protection layer are made by Polyvinyl chloride (PVC).

Wherein the first protection layer and the second protection layer are of one-layer structure or of multiple-layer structure.

Wherein plasma gas is adopted to process the organic photoresist materials.

Wherein the plasma gas is Tetrafluoromethane or SF6.

In another aspect, a package method of TFT having a hydrophobic layer includes: forming a first protection layer on a surface of the TFT; forming a second protection layer on an external surface of the first protection layer; and forming the hydrophobic layer on an external surface of the second protection layer.

Wherein the hydrophobic layer is of one-layer structure or of multiple-layer structure.

Wherein the hydrophobic layer is made by organic photoresist material.

Wherein the hydrophobic layer is formed by applying a plasma treatment toward the organic photoresist material.

Wherein the first protection layer and the second protection layer are made by insulating materials.

Wherein the first protection layer and the second protection layer are made by Polyvinyl chloride (PVC).

Wherein the first protection layer d the second protection layer are of one-layer structure or of multiple-layer structure.

Wherein plasma gas is adopted to process the organic photoresist materials.

Wherein the plasma gas is Tetrafluoromethane or SF6.

In another aspect, a TFT liquid crystal module includes a TFT structure unit formed by the above package method.

Compared with the conventional technology, the organic photoresist layer is formed on the external surface of the TFT protection layer. The organic photoresist materials are then applied with the plasma gas treatment to obtain the hydrophobic layer. As the hydrophobic layer does not absorb the moisture, that is, the moisture are cut off. Thus, the TFT performance may be kept stable.

### BRIEF DESCRIPTION OF THE DRAWINGS

FIG. 1 is a schematic view of the conventional TFT package structure.

FIG. 2 is a schematic view of the TFT package structure having a hydrophobic layer in accordance with one embodiment.

FIG. 3 is a flowchart illustrating the TFT package method in accordance with one embodiment.

FIG. 4 is a schematic view of the first protection layer and the second protection layer manufactured by the TFT package method of FIG. 3; and

FIG. 5 is a schematic view of the hydrophobic layer formed by the TFT package method of FIG. 3.

### DETAILED DESCRIPTION OF THE EMBODIMENTS

Embodiments of the invention will now be described more fully hereinafter with reference to the accompanying drawings, in which embodiments of the invention are shown.

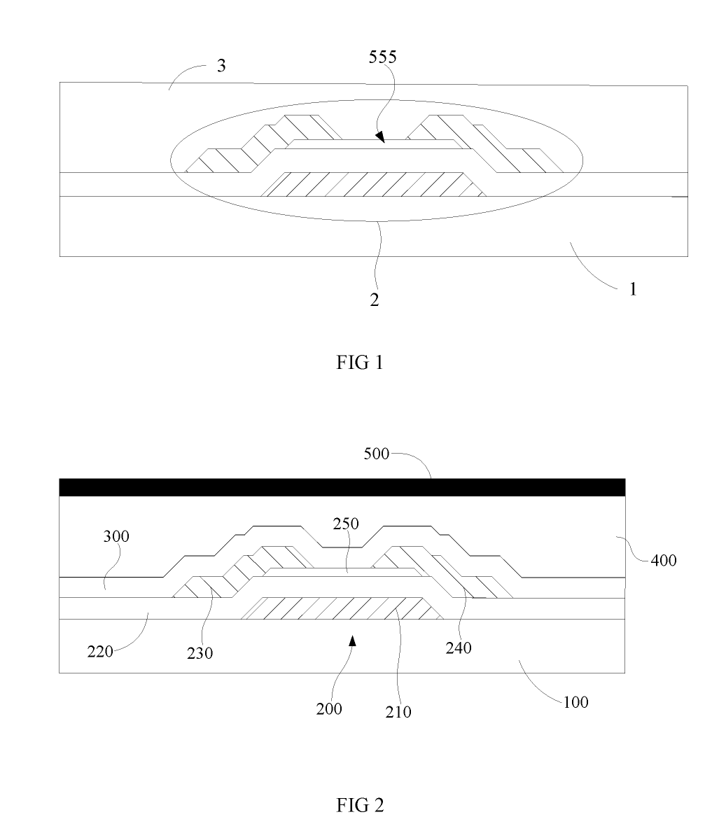

FIG. 2 is a schematic view of the TFT package structure having a hydrophobic layer in accordance with one embodiment. The package structure includes, but not limited to: a substrate 100, a TFT structure unit 200, a first protection layer 300, a second protection layer 400, and a hydrophobic layer 500.

Specifically, the TFT structure unit 200 is arranged on the substrate 100. The TFT structure unit 200 further includes a gate 210, a semiconductor layer 220, a source 230, a drain 240, and a metal oxide layer 250. The detailed structure of the TFT structure unit 200 may be understood by persons skilled in the art, and thus are omitted hereinafter.

The first protection layer 300 is configured as a passivation layer covering an external surface of the TFT structure unit 200, wherein the first protection layer 300 is made by insulating materials. Preferably, the first protection layer 300 may be made by Polyvinyl chloride (PVC). The first protection layer 300 may be of one-layer structure or of multiple-layer structure.

The second protection layer 400 is configured as a flat layer covering the external surface of the first protection layer 300, wherein the second protection layer 400 may be made by insulating materials. Preferably, the second protection layer 400 may be made by Polyvinyl chloride (PVC). The second protection layer 400 may be of one-layer structure or of multiple-layer structure. To enhance the water-proof performance of the TFT, the hydrophobic layer 500 is configured on the external surface of the second protection layer 400. Similarly, the hydrophobic layer 500 may be of one-layer structure or of multiple-layer structure. Preferably, the hydrophobic layer 500 may be made by organic photoresist materials, and the organic photoresist materials may be formed as the final structure of the hydrophobic layer after the plasma gas treatment, wherein the plasma gas may be Tetrafluoromethane or SF6.

Compared with the conventional technology, the organic photoresist layer is formed on the external surface of the TFT protection layer. The organic photoresist materials are then applied with the plasma gas treatment to obtain the hydrophobic layer. As the hydrophobic layer does not absorb the moisture, that is, the moisture are cut off. Thus, the TFT performance may be kept stable.

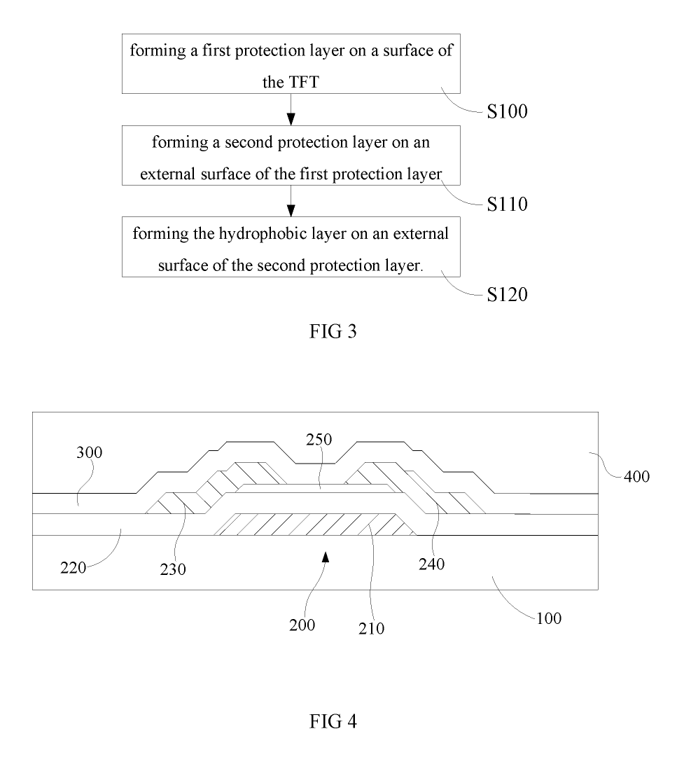

FIG. 3 is a flowchart illustrating the TFT package method in accordance with one embodiment. The method includes, but not limited to, the following steps.

In step S100, forming a first protection layer on a surface of the TFT.

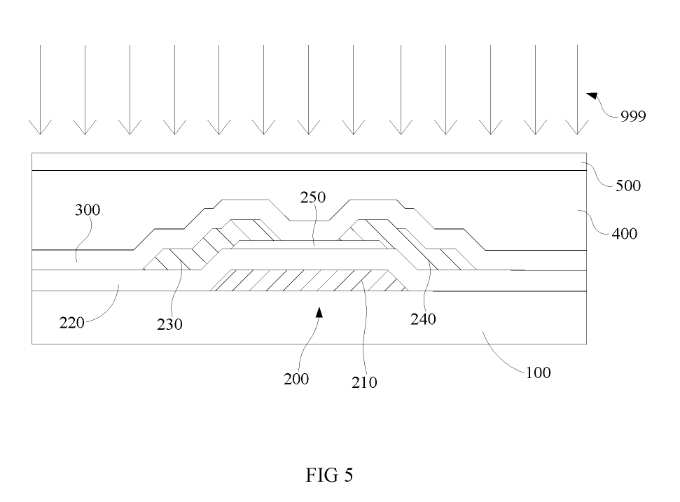

FIG. 4 is a schematic view of the first protection layer and the second protection layer manufactured by the TFT package method of FIG. 3. In step S100, the TFT structure unit 200 is arranged on the substrate 100, wherein the TFT structure unit 200 further includes a gate 210, a semiconductor layer 220, a source 230, a drain 240, and a metal oxide layer 250. The detailed structure of the TFT structure unit 200 may be understood by persons skilled in the art, and thus are omitted hereinafter.

The first protection layer 300 covers the external surface of the TFT structure unit 200, wherein the first protection layer 300 is made by insulating materials. Preferably, the first protection layer 300 may be made by Polyvinyl chloride (PVC). The first protection layer 300 may be of one-layer structure or of multiple-layer structure.

In step S110, forming a second protection layer on an external surface of the first protection layer.

In step S110, the second protection layer 400 covers the external surface of the first protection layer 300, wherein the second protection layer 400 may be made by insulating materials. Preferably, the second protection layer 400 may be made by Polyvinyl chloride (PVC). The second protection layer 400 may be of one-layer structure or of multiple-layer structure.

In step S120, forming a hydrophobic layer on the external surface of the second protection layer.

To enhance the water-proof performance of the TFT, the hydrophobic layer 500 is configured on the external surface of the second protection layer 400. Similarly, the hydrophobic layer 500 may be of one-layer structure or of multiple-layer structure. Preferably, the hydrophobic layer 500 may be made by organic photoresist materials, and the organic photoresist materials may be formed as the final structure of the hydrophobic layer after the plasma gas treatment, wherein the plasma gas 999 may be Tetrafluoromethane or SF6. FIG. 5 is a schematic view of the hydrophobic layer formed by the TFT package method of FIG. 3, and the resulting TFT package structure is shown in FIG. 2.

Compared with the conventional technology, the organic photoresist layer is formed on the external surface of the TFT protection layer. The organic photoresist materials are then applied with the plasma gas treatment to obtain the hydrophobic layer. As the hydrophobic layer does not absorb the moisture, that is, the moisture are cut off. Thus, the TFT performance may be kept stable.

In addition, a liquid crystal module includes the TFT structure unit, and the TFT structure unit is packaged by the above package method in the above embodiments. Other structures of the liquid crystal module may be conceived by persons skilled in the art, and thus are omitted hereinafter.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A TFT package structure, comprising:
a first protection layer covering a surface of the TFT, a second protection layer arranged above the first protection layer, and a hydrophobic layer arranged above the second protection layer.

2. The TFT package structure as claimed in claim 1, wherein the hydrophobic layer is of one-layer structure or of multiple-layer structure.

3. The TFT package structure as claimed in claim 1, wherein the hydrophobic layer is made by organic photoresist material.

4. The TFT package structure as claimed in claim 3, wherein the hydrophobic layer is formed by applying a plasma treatment toward the organic photoresist material.

5. The TFT package structure as claimed in claim 1, wherein the first protection layer and the second protection layer are made by insulating materials.

6. The TFT package structure as claimed in claim 5, wherein the first protection layer and the second protection layer are made by Polyvinyl chloride (PVC).

7. The TFT package structure as claimed in claim 5, wherein the first protection layer an second protection layer are of one-layer structure or of multiple-layer structure.

8. The TFT package structure as claimed in claim 4, wherein plasma gas is adopted to process the organic photoresist materials.

9. The TFT package structure as claimed in claim 8, wherein the plasma gas is Tetrafluoromethane or SF6.

10. A package method of TFT having a hydrophobic layer, comprising:
forming a first protection layer on a surface of the TFT;
forming a second protection layer on an external surface of the first protection layer; and
forming the hydrophobic layer on an external surface of the second protection layer.

11. The package method as claimed in claim 10, wherein the hydrophobic layer is of one-layer structure or of multiple-layer structure.

12. The package method as claimed in claim 10, wherein the hydrophobic layer is made by organic photoresist material.

13. The package method as claimed in claim 12, wherein the hydrophobic layer is formed by applying a plasma treatment toward the organic photoresist material.

14. The package method as claimed in claim 10, wherein the first protection layer and the second protection layer are made by insulating materials.

15. The package method as claimed in claim 14, wherein the first protection layer and the second protection layer are made by Polyvinyl chloride (PVC).

16. The package method as claimed in claim 14, wherein the first protection layer and the second protection layer are of one-layer structure or of multiple-layer structure.

17. The package method as claimed in claim 13, wherein plasma gas is adopted to process the organic photoresist materials.

18. The package method as claimed in claim 17, wherein the plasma gas is Tetrafluoromethane or SF6.

19. A TFT liquid crystal module comprises a TFT structure unit formed by the package method of claim 10.
